(19) United States
(12) Patent Application Publication
(10) Pub. No.: US 2023/0130254 A1
(43) Pub. Date: Apr. 27, 2023

(54) PROTECTIVE HOUSING FOR CONTROL LOGIC OF AN ELECTRIC VEHICLE

(71) Applicant: Endera Corporation, Casper, WY (US)

(72) Inventors: Alfredo Gonzalez, Corona, CA (US); Enrique Garcia, San Gabriel, CA (US); Shashvat Mehta, San Gabriel, CA (US); Thomas Kosbau, Casper, WY (US); John J. Walsh, Casper, WY (US)

(21) Appl. No.: 17/973,036

(22) Filed: Oct. 25, 2022

Related U.S. Application Data
(60) Provisional application No. 63/271,601, filed on Oct. 25, 2021.

(51) Int. Cl. B60R 16/023; H05K 5/02; H02G 3/08; B60L 50/60

(52) U.S. Cl. CPC B60R 16/0238; B60L 50/60; H02G 3/08; H05K 5/0217; H05K 5/0247

(57) ABSTRACT

A protective housing for a central electrical system deployed within an electric vehicle is described. The protective housing features a first housing layer, a second housing layer and a third housing layer. The first housing layer is configured to support and protect one or more power distribution units responsible for distributing high-voltage power to components within the electric vehicle. The second housing layer is positioned above the first housing layer, where the second housing layer is to support and protect a power charger that disseminates supplied input power to a high-voltage junction box for routing to the battery system of the vehicle. The third housing layer is positioned above the second housing layer, where the third housing layer is to support a high-voltage junction box that handles the routing of power between the distribution unit(s), the charger and the battery system.

### CROSS-REFERENCE TO RELATED APPLICATIONS

This application claims the benefit of priority on U.S. Provisional Application No. 63/271,601 filed Oct. 25, 2021, the entire contents of which are incorporated by reference herein

### FIELD

Embodiments of the disclosure relate to the field of vehicle infrastructure, and more specifically, one embodiment of the disclosure relates to protective housing for control logic of an electrical vehicle.

### GENERAL BACKGROUND

Multi-passenger transportation provides many benefits to individuals, communities, and the local economy. For decades, it has been widely recognized that multi-passenger transportation can reduce air pollution and traffic congestion that have plagued our cities, especially in high density areas. The usage of mass-transit electric vehicles would assist in making larger strides to reduce carbon-monoxide (CO) emissions, a contributing factor in global climate change.

However, with electrification, vehicle controls are needed to coordinate operability of electrification components such as a high-voltage junction box, a direct current-to-direct current (DC-DC) converter, power distribution units, or the like. Consolidation of the vehicle electrical controls is vital to reduce the amount and length of interconnects needed to connect the electrification components. By failing to take advantage of vehicle electrical control consolidation, especially within an unoccupied engine bay resulting from the substitution of an internal combustion engine for an electric motor, conventional electric vehicle designs are subject to a number of disadvantages. For example, conventional electric vehicles commonly feature redundant interconnect loops between different electrification components, which wastes resources, increases the weight of the electric vehicle thereby decreasing travel distance of the electric vehicle per charge, and potentially subjects the electric vehicle to maintenance or operational issues.

A more efficient layout and protective infrastructure for collectively housing electrical control logic for a vehicle is needed.

### BRIEF DESCRIPTION OF THE DRAWINGS

Embodiments of the invention are illustrated by way of example and not by way of limitation in the figures of the accompanying drawings, in which like references indicate similar elements and in which:

FIG. 1 is a perspective view of a chassis for an electric vehicle with an electrical control system installed within a protective housing mounted on the chassis.

FIG. 2 is a perspective view of electrification components of the electrical control system of FIG. 1 installed within the protective housing.

FIG. 3 is a perspective view of the protective housing of FIGS. 1-2.

FIG. 4 is a perspective view of a high voltage junction box of the electrical control system deployed on the protective housing of FIG. 2.

FIG. 5 is a perspective view of a charger of the electrical control system deployed within the protective housing of FIG. 2.

FIG. 6 is a perspective view of a plurality of power distribution units of the electrical control system deployed within the protective housing of FIG. 2.

FIG. 7 is a perspective view of a power converter of the electrical control system deployed on the protective housing of FIG. 2.

FIG. 8 is an illustrative alternative embodiment of an attachment component for coupling the power converter to the protective housing.

FIG. 9 is an illustrative view of the flow of voltage and current through electrification components of the electrical control system during a normal operational state of the electric vehicle and a charging state of the electric vehicle

### DETAILED DESCRIPTION

According to one embodiment of the disclosure, a centralized, electrical control system installed within a protective housing mounted on a vehicle chassis is described. The electrical control system may include, but is not limited or restricted to the following electrification components: a high voltage junction box, an on-board charger, one or more power distribution units, and a power (DC-to-DC) converter. Herein, the protective housing is positioned on a cradle within an area of the chassis previously utilized as an internal combustion engine bay.

In general, the high voltage (HV) junction box is configured to receive stored HV power (e.g., voltage > 200 V, amperage > 100 A) from multiple battery packs via dedicated HV interconnects and to provide the stored HV power to a power distribution unit. Additionally, the HV junction box is configured to receive input HV power from a charger and to provide the input HV power to the battery packs. Prior to providing of the stored HV power to the power distribution unit, as optional functionality, the HV junction box may be configured to conduct power conditioning operations to adjust voltage and/or amperage of the stored HV power.

The on-board charger is configured to manage the charging of the battery packs installed within the electric vehicle. More specifically, the charger includes a charging interface that is adapted to receive HV power input from a charging source and provide converted HV power to the HV junction box. Herein, the charger is configured to convert the received HV power from the charging station into a power level that is safe for use by the electrical control system. The converted HV power is provided to the HV junction box to be provided to the battery packs for re-charging these battery packs.

The one or more power distribution units feature control logic configured to manage the distribution of power to electrification components within the electric vehicle. As described below, a plurality of power distribution units may be deployed as part of the electrical control system to provide a greater number of power ports for connectivity to a greater number of electrification components within the electric vehicle. The power distribution units are electrically coupled together, where a first power distribution unit is electrically coupled to the HV junction box and at least a second power distribution unit is electrically coupled to the first power distribution unit to receive HV power for dissemination to different electrification components such as the electric motor and the power converter.

The power converter features logic to convert power at a first voltage level to power at a second voltage level. For example, the power converter may be a direct current to direct current (DC-to-DC) power converter that converts power greater than 200 volt (200 V) power signals into power signals of lesser voltage such as 24 V power signals, 12 V power signals, or the like.

### I. Summary

More specifically, for a chassis configured to support a multi-battery pack system as described below, an electrical control system is installed to manage the routing and dissemination of power throughout the electric vehicle, including the routing of high-voltage (HV) power to and from the battery pack system. The chassis includes a cradle, which is used to secure the protective housing for the electrical control system. The protective housing is a framework constructed with a first housing layer, a second housing layer positioned above the first housing layer, and a third housing player positioned above the second housing layer. Herein, the plurality of power distribution units is deployed within the first housing layer. The charger is deployed within the second housing layer, and the high voltage junction box is deployed on the third housing layer. The power converter may be attached to a back end of the framework of the protective housing between base member pairs forming a portion of the outer perimeter of the protective housing.

The protective housing includes at least two base member pairs to which a side frame member is coupled proximate to a downward end of each base member forming a base member pair. Each side frame member provides stability to the protective housing and delineates side boundaries for a raised, first storage area within the first housing layer of the protective housing. The first storage area is formed by a bottom frame member extending from a first side of the first housing layer to a second side, including extending across the front end of the first housing layer. One or more of the power distribution units are inserted into the first housing layer through an opening formed at the back end of the protective housing and secured to the bottom frame member.

As described below, a base member pair features a first angled frame member and a second angled frame member. The first angled frame member is coupled to and extends from the bottom frame member proximate to a first end of a first segment of the bottom frame member that corresponds to a first side of the protective housing, and a second angled frame member is coupled to and extends from a second end of the first segment. At least a first power distribution unit and a second power distribution unit are slidably inserted into the first housing layer with a power input/output (I/O) interface for the first power distribution unit being oriented facing the back end of the protective housing. A power I/O interface for the second power distribution unit may be oriented facing the back end of the protective housing.

The second housing layer is formed by a mid-frame member positioned above the base frame member. The mid-frame member includes four segments collectively positioned around a periphery of the second housing layer. A first support frame member is coupled to and extends from a first segment of the mid-frame member to a third segment of the mid-frame member generally oriented in parallel with the first segment. Positioned at the back end of the protective housing, the fourth segment of the mid-frame member is maintained in an elevated position by the first support frame member. A second support frame member is coupled to and extends from a mid-section of a second (front) segment of the mid-frame member and a mid-section of a fourth (back) segment of the mid-frame member. The second support frame member is arranged to assist in supporting and affixing the power converter to the protective housing.

Additionally, a first edge frame member is positioned on a first segment of the mid-frame member and coupled to and extends between base members of the second base member pair. A second edge frame member is positioned on a third segment of the mid-frame member and coupled to and extends between base members of the first base member pair. The power charger is coupled to the protective housing by at least coupling the power charger to both the first segment and the third segment of the mid-frame member.

The third housing layer is formed by a first top frame member and a second top frame member intersecting different segments of the first top frame member. The first top frame member and the second top frame member collectively form the third housing layer. The first top frame member is coupled to an angled top end portion of each of the base members. The HV junction box is coupled to and positioned on upper surfaces of the first top frame member and the second top frame member.

An attachment component, operating as a bracket, may be affixed to the power converter. The attachment component is configured for coupling to the first support frame member and the first top frame member. The attachment component, including the preinstalled power converter, may be coupled to the protective housing after installation of at least the charger.

### II. Terminology

In the following description, certain terminology is used to describe aspects of the invention. The term “logic” is representative of hardware and/or software that is configured to perform one or more functions. The hardware associated with the logic may include circuitry having data processing or data storage such as non-transitory storage medium. The software associated with the logic may include one or more software modules. The software modules may operate as an executable application, a daemon application, an application programming interface (API), a subroutine, a function, a procedure, a plug-in, an applet, a servlet, a routine, source code, a shared library/dynamic load library, or one or more instructions. The software module(s) may be stored in any type of a suitable non-transitory storage medium, or transitory storage medium (e.g., electrical, optical, acoustical or other form of propagated signals such as carrier waves, infrared signals, or digital signals). Examples of non-transitory storage medium may include, but are not limited or restricted to a programmable circuit; a semiconductor memory; non-persistent storage such as volatile memory (e.g., any type of random access memory “RAM”); persistent storage such as non-volatile memory (e.g., read-only memory “ROM”, power-backed RAM, flash memory, phase-change memory, etc.), a solid-state drive, hard disk drive, an optical disc drive, or a portable memory device.

Both of the terms “member” and “segment” are representative of a mechanical structure.

An “electric vehicle” generally refers to a multi-passenger conveyance such as an automotive conveyance that is configured to at least partially rely on electrification for movement such as a hybrid or low-emission, plug-in multi-passenger conveyance. Examples of different types of multi-passenger conveyances may include, but are not limited or restricted to a shuttle van, an electric bus, a limousine, an airplane, a train, or the other multi-passenger vehicle that relies on electrification. However, it is contemplated that the electric vehicle may include an internal combustion engine to assist in propulsion.

A “chassis” generally refers to the main supporting structure of an electric vehicle to which electrification components are attached. Herein, the chassis includes a pair of frame rails and one or more cross members. A “frame rail” is a component of the electric vehicle frame that extends longitudinally along the length of the frame and operates as a supporting structure for vehicle components. A “cross member” generally refers to a component arranged for extending between and coupling to the pair of frame rails forming the chassis. Collectively, the frame rails and the cross member(s) for the frame, which provides a support structure for the protective housing described below.

The term “interconnect” generally refers to a propagation path for a prescribed element to an electrification component deployed within a vehicle, where the prescribed element may include electrical power such as a current (amperage) and/or a voltage. As an illustrative example, a first interconnect may be configured as a high-voltage (HV) interconnect, which supports a conveyance of power with a voltage approximately ranging between 200-800 volts and a current ranging from 200-600 amperes. Other interconnects may be configured to support the conveyance of power at lower voltages and/or amperages.

Finally, the terms “or” and “and/or” as used herein are to be interpreted as inclusive or meaning any one or any combination. As an example, “A, B or C” or “A, B and/or C” mean “any of the following: A; B; C; A and B; A and C; B and C; A, B and C.” An exception to this definition will occur only when a combination of elements, functions, steps or acts are in some way inherently mutually exclusive.

As this invention is susceptible to embodiments of many different forms, it is intended that the present disclosure is to be considered as an example of the principles of the invention and not intended to limit the invention to the specific embodiments shown and described.

### III. Vehicle-Based System Architecture

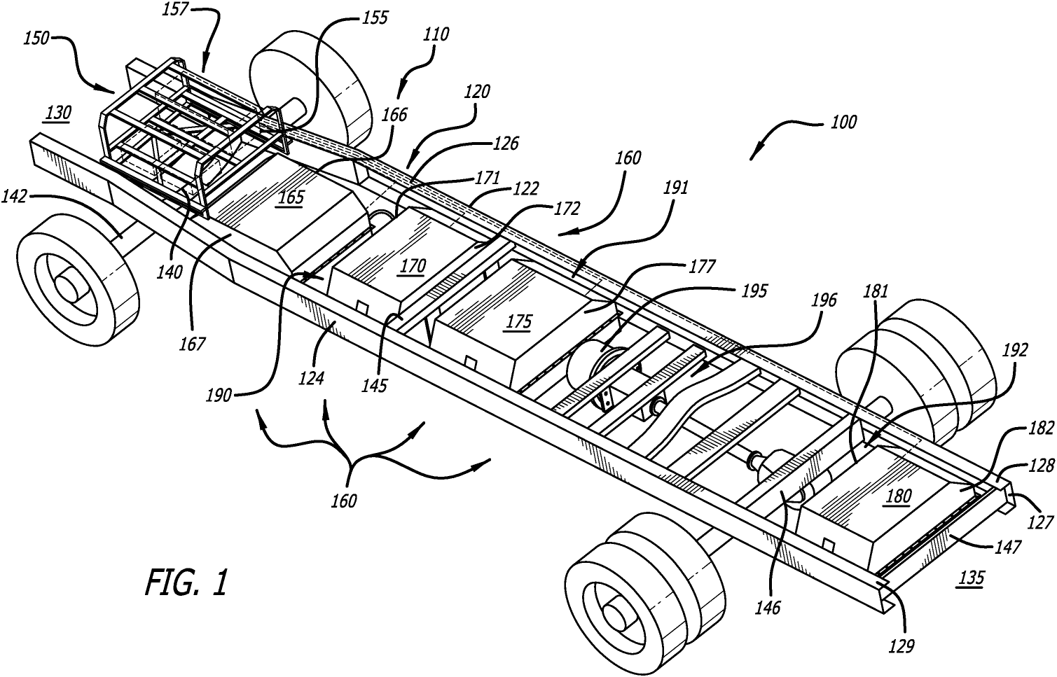

Referred to FIG. 1, a perspective view of an exemplary embodiment of a chassis 110 of an electric vehicle 100 is shown, where the chassis 110 is configured to support a battery system 160 (e.g., a four-pack battery system). Herein, the chassis 110 features parallel frame rails 120 extending from a front end 130 to a back end 135 of the electric vehicle 100. As shown, the parallel frame rails 120 include a first frame rail 122 and a second frame rail 124, which are coupled to a conventional cradle 140 positioned to at least partially overlay a front axle 142 of the electric vehicle 100. As shown, the cradle 140 provides support for a protective housing 150, which includes an electrical control system 155 configured for routing and dissemination of power throughout the electric vehicle 100, including the routing of power to and from the battery system 160. The electrical control system 155 includes a plurality of electrification components 157 configured for power management directed to the distribution and usage of power throughout the electric vehicle 100.

As shown in FIG. 1, as an illustrated embodiment, a first interconnect 126 is positioned within a channel 127 of the first frame rail 122. The first interconnect 126 corresponds to a plurality of high-voltage (HV) power cables that propagates HV power from the electrical control system 155 to the battery system 160 during a charging and propagates HV power from the battery system 160 to the electrical control system 155 during a normal operating state. The first interconnect 126 is position along a passenger-side of the electric vehicle 100.

According to one embodiment of the disclosure, the four-pack battery system 160 includes a first battery pack 165, a second battery pack 170, a third battery pack 175 and a fourth battery pack 180, where all of the battery packs 165, 170, 175 and 180 are secured to the chassis 110 by mounting brackets (not shown). Each of the battery packs 165, 170, 175 and/or 180 feature a housing for encasing a collection of battery cells such as lithium-ion cells (e.g., lithium-ion manganese oxide batteries being a lithium-ion cell that uses manganese dioxide (MnO₂) as the cathode material, lithium iron phosphate batteries, etc.).

According to one embodiment of the disclosure, as shown, the first battery pack 165 and the second battery pack 170 are installed within a first installation area 190 defined by the first frame rail 122, the second frame rail 124, the cradle 140 and a first cross member 145 being one of a plurality of cross members. Herein, the first battery pack 165 is positioned with a longitudinal orientation, where lengthwise sides 166/167 of the first battery pack 165 are oriented to be generally in parallel with the first frame rail 122 and the second frame rail 124. In contrast, the second battery pack 170 is positioned with a latitudinal orientation, where lengthwise sides 171/172 of the second battery pack 170 are oriented to be generally orthogonal to the first frame rail 122 and the second frame rail 124.

The third battery pack 175 is installed within a second installation area 191, which is defined by the first frame rail 122, the second frame rail 124, the first cross member 145 and an electric motor 195 that is part of a drivetrain 196 for the electric vehicle 100. According to this embodiment of the disclosure, the third battery pack 175 is positioned with a latitudinal orientation, where lengthwise sides 176/177 of the third battery pack 175 are oriented to be generally orthogonal to the first frame rail 122 and the second frame rail 124.

The fourth battery pack 180 is installed within a third installation area 192, which is defined by the first frame rail 122, the second frame rail 124, a second cross member 146 and a third cross member 147 that is coupled to end portions 128 and 129 of the first frame rail 122 and the second frame rail 124, respectively. According to this embodiment of the disclosure, the fourth battery pack 180 is positioned with a latitudinal orientation, where lengthwise sides 181/182 of the fourth battery pack 180 are oriented to be generally orthogonal to the first frame rail 122 and the second frame rail 124.

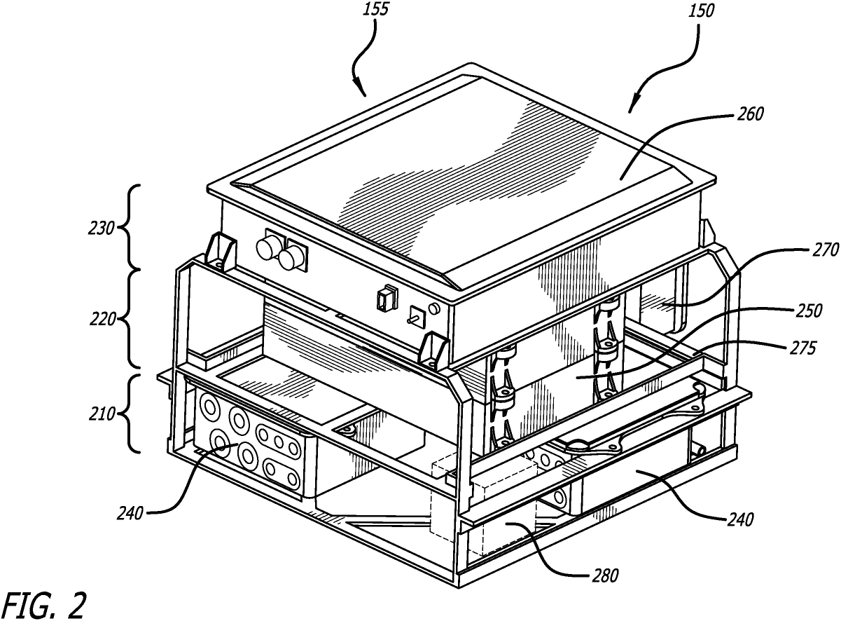

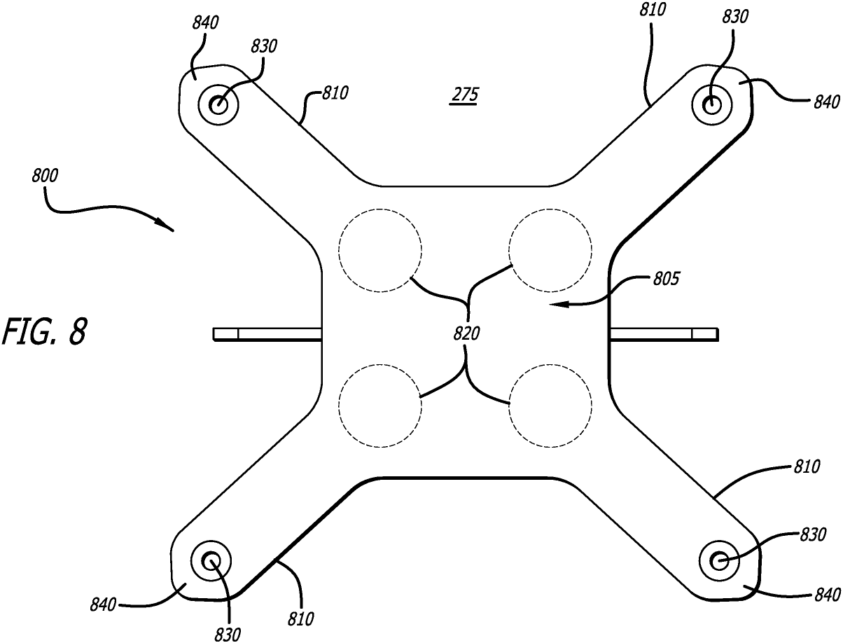

Referring now to FIG. 2, the protective housing 150 includes the electrical control system 155, which is configured for power management directed at least to the usage and distribution of power throughout the electric vehicle 100 of FIG. 1. The protective housing 150 is a protective framework constructed with a plurality of housing layers 200, including a first housing layer 210, a second housing layer 220 positioned above the first housing layer 210, and a third housing layer 230 positioned above the second housing layer 220. Herein, according to one embodiment of the disclosure, the first housing layer 210 maintains a first set (e.g., one or more) of electrification components 240 such as one or more power distribution units 240 (hereinafter, “power distribution unit(s)”). A second set of electrification components 250, such as an on-board charger 250 for example, may be deployed within the second housing layer 220 while a first set of electrification components (e.g., a high voltage junction box 260) is deployed on the third housing layer 230. A power converter 270 may be affixed to the protective housing by an attachment component 275 such as a bracket (see FIG. 8).

Optionally, a vehicle control unit (VCU) 280 may be positioned within the protective housing 150. The VCU 280 may be configured to apply controls to the powertrain (e.g., electric motor, gearbox, etc.) such as torque coordination, gearshift strategies, charging control, on board diagnosis, thermal management for control of a flow of thermal mixtures through conduits within the electric vehicle 100, or the like.

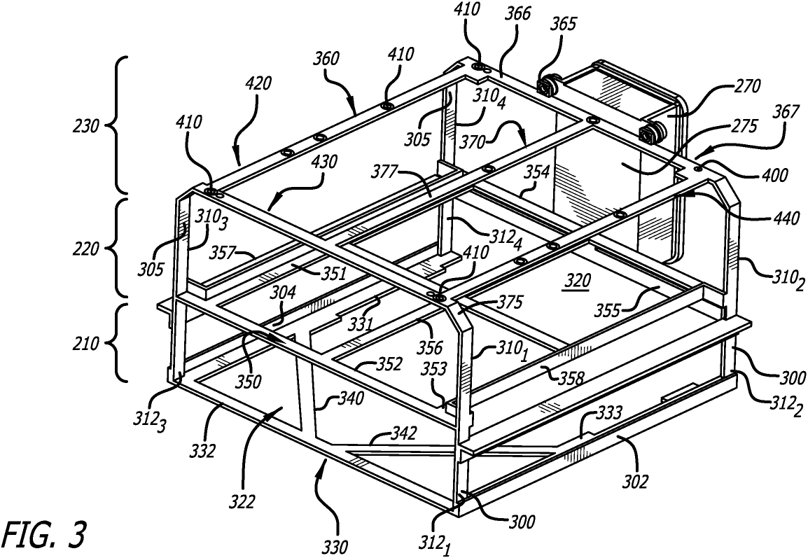

As shown in FIG. 3, the protective housing 150 includes a plurality of base member pairs 300 and 305, which form a general framework for the protective housing 150. To provide stability to the protective housing 150 and delineates side boundaries for a first storage area within the first housing layer 210, a first side frame member 302 is coupled proximate to a lower end 312₁-312₂ of each base member 310₁-310₂ of the base member pair 300 and a second side frame member 304 is coupled proximate to a lower end 312₃-312₄ of each base member 310₃-310₄ of the base member pair 305. An opening 320 within a back end 202 of the protective housing 150 allows for insertion of the power distribution unit(s) 240 into the first housing layer 210 prior to securing the power distribution unit(s) 240 to the protective housing 150 as shown in FIG. 2.

The first housing layer 210 is formed by a bottom frame member 330, which includes segments 331-333 positioned around the periphery of the first housing layer 210 to operate as the support framework for electrification components installed therein. A first angled frame member 340 is coupled to and extends from the first segment 331 of the bottom frame member 330 to the second segment 332 of the bottom frame member 330, and a second angled frame member 342 is coupled to and extends from the second segment 332 of the bottom frame member 330 to the third segment 333 of the bottom frame member 330. The power distribution unit(s) 240 are slidably inserted into the first housing layer 210 and are supported by the first angled frame member 340 and the second angled frame member 342, respectively.

The second housing layer 220 is formed by a mid-frame member 350, which includes a first segment 351 a second segment 352, a third segment 353 and a fourth segment 354 positioned around the entire periphery of the second housing layer 220 to operate as the support framework for electrification components installed thereon. A first support frame member 355 is coupled to and extends from the first segment 351 of the mid-frame member 350 to the third segment 353 of the mid-frame member 350. The fourth segment 354 of the mid-frame member 350 is maintained in an elevated position by the first support frame member 355. A second support frame member 356 is coupled between the second segment 352 and the fourth segment 354 of the mid-frame member 350. The second support frame member 356 is arranged to assist in supporting and affixing the power converter 270 to the protective housing 150.

Additionally, a first edge frame member 357 is positioned on the first segment 351 of the mid-frame member 350, where the first edge frame member 357 is coupled to and extends between base members 310₃ and 310₄ of the second base member pair 305. A second edge frame member 358 is positioned on the third segment 358 of the mid-frame member, where the second edge frame member 358 is coupled to and extends between base members 310₁ and 310₂ of the first base member pair 300. As shown in FIG. 2, the power charger 250 is coupled to the protective housing 150 by affixing the power charger 250 to at least the first segment 351 and the third segment 353 of the mid-frame member 350.

The third housing layer 230 is formed by a first top frame member 360 and a second top frame member 370 intersecting different segments of the first top frame member 360. The first top frame member 360 and the second top frame member 370 collectively form the third housing layer 230. The first top frame member 360 is coupled to an angled top end portion 375 of each of the base member 310₁-310₄. The HV junction box 260 is coupled to and positioned on upper surfaces 377 of the first top frame member 360 and the second top frame member 370.

The attachment component 275, operating as a bracket, is coupled to the power converter 270. The attachment component 275 is configured for coupling to the first support frame member 355, such as insertion of a fastener (e.g., bolt, pin, screw, etc.) through apertures predrilled into the first support frame member 355 and secured by a fastening element (e.g., nut, clamp, etc.). Alternatively, the attachment component may be coupled by other means such as welding or the like. The attachment component 275 is further configured for coupling to the first top frame member 360, such as insertion of a fastener (not shown) through a preformed tab 365 extending from a top surface 366 of a back segment 367 of the first top frame member 360 and securing of the fastener by a fastening element.

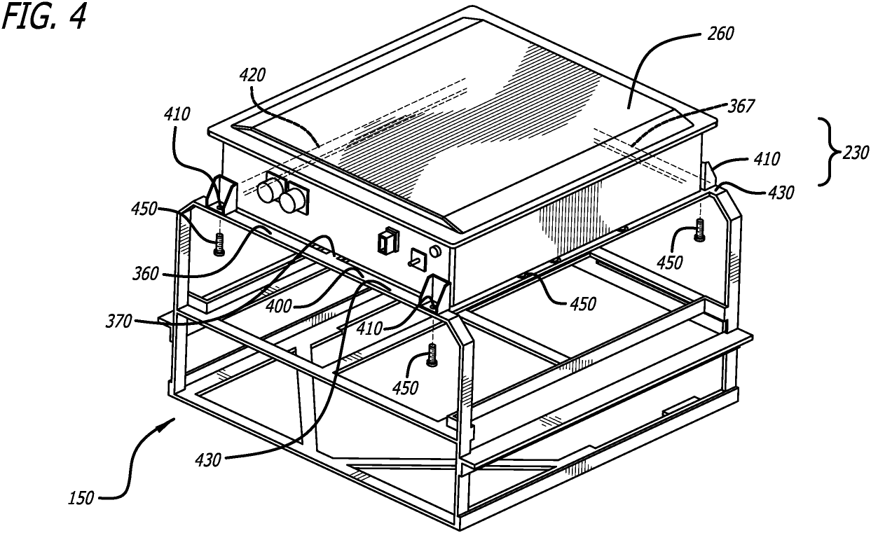

Referring now to FIG. 4, a perspective view of the protective housing 150 deploying the HV junction box 260 is shown. Herein, the HV junction box 260 is secured at the third housing layer 230 of the protective housing 150. More specifically, the HV junction box 260 is affixed to an upper surface 400 of the first top frame member 360 and the second top frame member 370. As shown in FIGS. 3-4, fastening apertures 410 are positioned along each of a first segment 420, a second segment 430, a third segment 440 and a fourth (back) segment 367. Herein, as shown, fasteners 450 (e.g., bolts, screws, pins, etc.) may be inserted through the fastener apertures 410 and contact a mating fastening element (e.g., threaded insert, nut, clamp, etc.) to secure the HV junction box 260 to the protective housing 150. It is contemplated that other fastening mechanisms may be used.

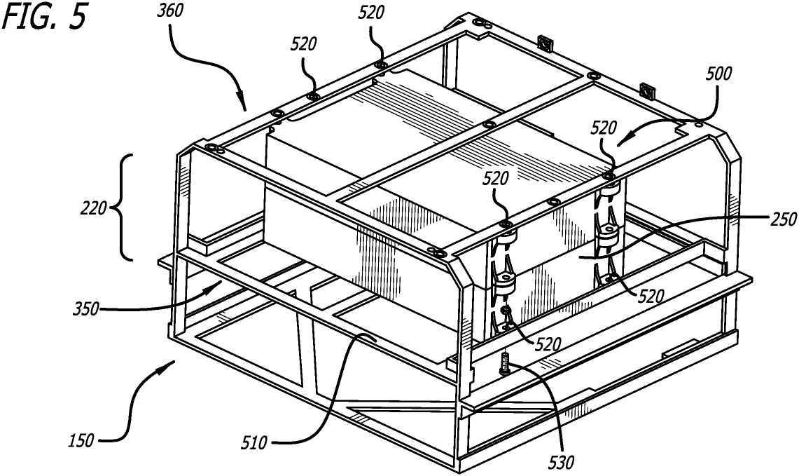

Referring to FIG. 5 is a perspective view of the power charger 250 of the electrical control system 155 of FIG. 2 deployed within the protective housing 150 is shown. Herein, the power charger 250 is inserted through a first opening 500 of the second housing layer 220, where the first opening 500 is formed between the mid-frame member 350 and the first top frame member 360. Thereafter, the power charger 250 affixed to an upper surface 510 of the mid-frame member 350. As shown in FIG. 3 and FIG. 5, fastening apertures 520 placed within (i) the first segment 351 and/or third segment 353 of the mid-frame member 350 and/or (i) the first segment 420 and/or third segment 440 of the first top frame member 360 are configured to receive fasteners 530 for insertion into the fastening apertures 520 and secured by a mating fastening element. It is contemplated that other fastening mechanisms may be used.

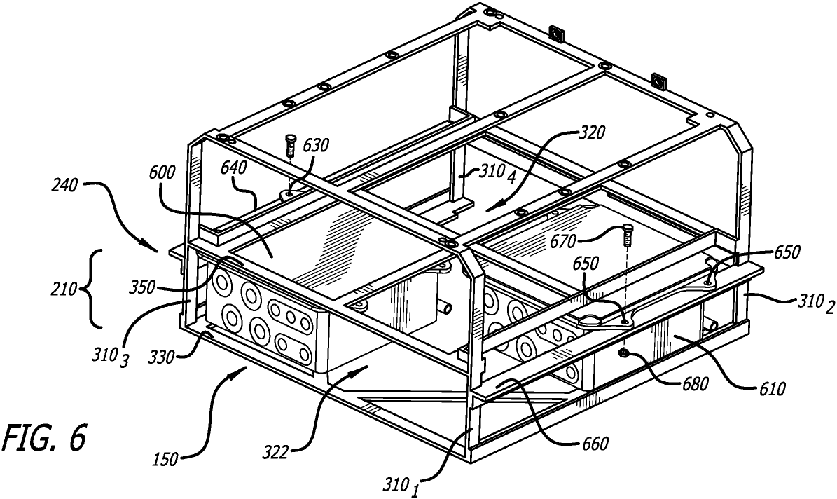

Referring now to FIG. 6, a perspective view of the plurality of power distribution unit(s) 240 of the electrical control system 155 of FIG. 2 deployed within the protective housing 150 is shown. Each of the power distribution unit(s) 240, such as a first power distribution unit 600 and a second power distribution unit 610 for example, is inserted through the opening 320 of the first housing layer 210. The opening 320 is formed between the mid-frame member 350 and the bottom frame member 330. Herein, according to one embodiment of the disclosure, the first power distribution unit 600 is coupled to the protective housing 150 by at least affixing one or more mounting tabs 630 to a first ridge member 640 that is coupled to the base members 310₃-310₄. The second power distribution unit 610 is coupled to the protective housing 150 by at least affixing one or more mounting tabs 650 to a second ridge member 660, which extends in a direction opposite the first ridge member 640 and is coupled to the base members 310₁-310₂. The affixation of the mounting tabs 630/650 may be accomplished by use of fasteners 670 inserted into apertures in the mounting tabs 630/650 aligned with apertures in the first/third segments 351/353 of the mid-section frame member 350 and secured by a mating fastening element 680 tightened to be proximate to the first/second ridge members 640/660.

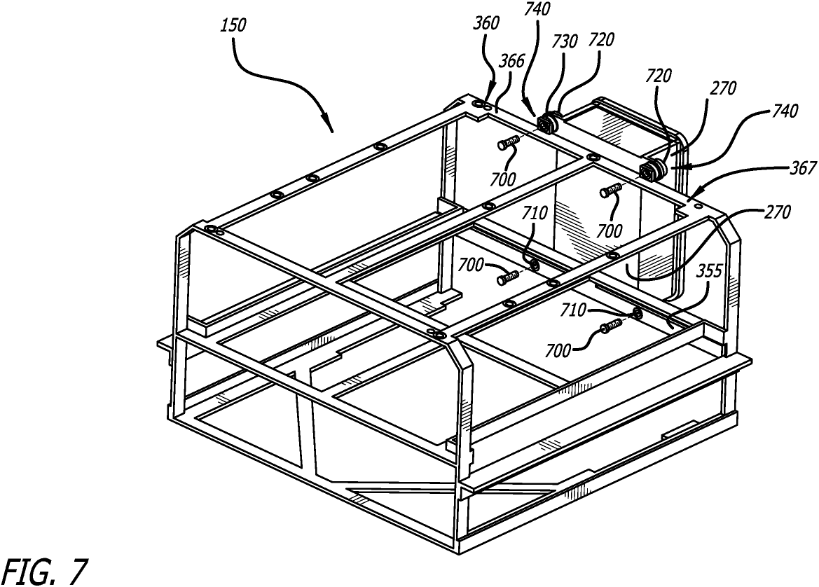

As shown in FIG. 7, an illustrated, perspective view of the power converter 270 of the electrical control system 155 of FIG. 2 attached to the protective housing 150 is shown. Herein, according to this embodiment of the disclosure, the power (DC-DC) converter 270 is coupled to the attachment component 275 operating as a bracket. The attachment component 275 is configured for coupling to the first support frame member 355, where the coupling may be conducted by a variety of attachment mechanisms including welding, fasteners 700 through apertures 710 predrilled into the first support frame member 355 and secured by a fastening element 720 provided by the attachment component 275 such as a grommet.

The attachment component 275 is further configured for coupling to the first top frame member 360, such as insertion of a through the preformed tab 365 extending from the top surface 366 of fourth (back) segment 367 of the first top frame member 360 and securing of the fastener by other fastening elements 720 such as grommets aligned with apertures 730 at edges 740 of the attachment component 275. A secondary embodiment of the attachment component 275 is shown in FIG. 8.

Referring now to FIG. 8, an illustrative view of a secondary embodiment of the attachment component 275 for coupling the power converter 270 to the protective housing 150 is shown. Herein, the attachment component 275 may include an attachment plate 800 with a central area 805 having extensions 810 protruding radially from corner areas 820 of the central area 805. Apertures 830 are formed at end portions of each of the extension 810 for aligning with corresponding apertures within the first support frame member 355, the performed tabs 365 extending from the first top frame member 360 as shown in FIG. 7. The apertures 830 would be aligned with a grommet for securing a fastener inserted therein.

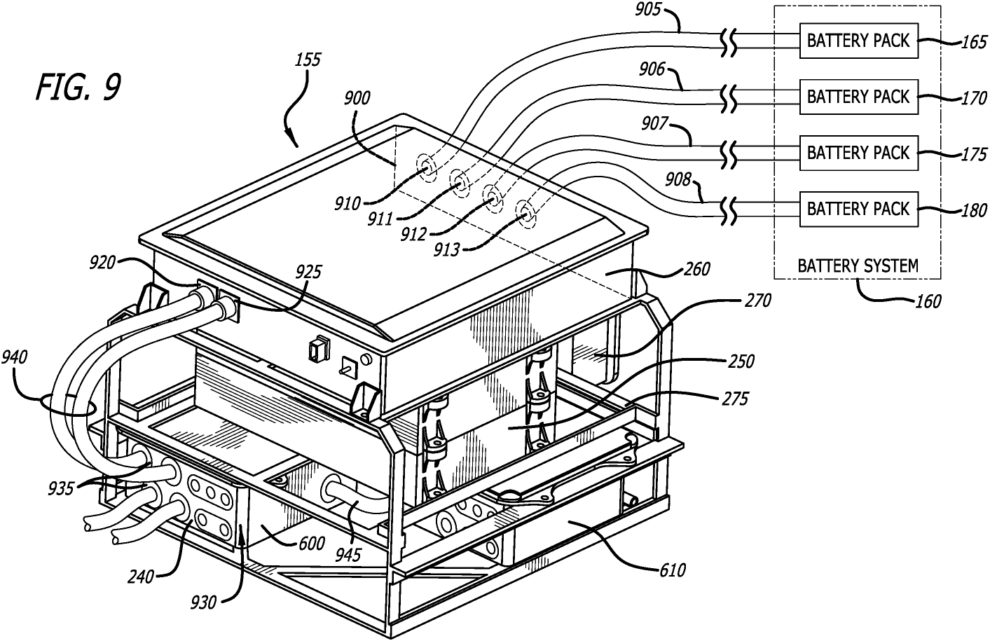

Referring now to FIG. 9, an illustrative view of the flow of power (e.g., voltage and current) through electrification components of the electrical control system 155 is shown. For this embodiment, the electrification components include power distribution units 240, charger 250, HV junction box 260, and power (DC-DC) converter 270.

With respect to a flow of power during a normal operational state of the electric vehicle, the HV junction box 260 features a first interface 900 and a second interface 920. Herein, the first interface 900 includes a plurality of power ports 910-913 configured to receive power propagated from the battery system 160 via HV power cables 905-908 collectively forming the first interconnect 126 of FIG. 1. As an illustrative example, according to one embodiment of the disclosure, each power port 910,... or 913 of the first interface 900 is adapted for coupling with a corresponding HV power cable 905,... or 908 of the HV power cables 905-908. As a result, for this embodiment, each of HV power cables 905-908 is uniquely designated to provide and supply power from one of the battery packs 165, 170, 175 and 180.

Alternatively, in accordance with another embodiment of the disclosure, the first interface 900 features four (4) power ports 910-913, where each power port 910-913 is adapted to receive one of the HV power cable 905-908. However, in lieu of the HV power cables 905-908 being separately designated for the battery packs 165, 170, 175 and 180, some or all of the HV power cable 905-908 may be shared by two or more battery packs of the battery packs 165, 170, 175 and 180 connected in parallel. This may occur when the battery system 160 is configured as a six battery-pack system. For example, while battery pack 165 may be electrically coupled to the HV junction box 260 via the first HV power cable 905, the battery packs 170 and 175 may be connected in parallel and coupled to the HV junction box 260 via the second HV power cable 906. This parallel connectivity would allow the vehicle to support up to eight battery packs without modification.

Upon receipt of the HV power via the interconnect 126, the HV junction box 260 provides the received HV power to the power distribution unit(s) 240 via a second interface 920. Prior to providing of the received HV power to the power distribution unit(s) 240, the HV junction box 260 may be configured to conduct power conditioning operations to adjust voltage and/or amperage levels of the received HV power.

As shown in FIG. 9, the second interface 920 of the HV junction box 260 features a second plurality of power ports 925 that are electrically coupled to a third plurality of power ports 935 of a power I/O interface 930 of the first power distribution unit 600. Herein, both power ports 925 and 935 are oriented in a direction facing the same direction of the protective housing 150 (e.g., front end 204) to minimize a run length of interconnects 940. Hence, the received HV power (e.g., 400 V, 500 A) is provided from the HV junction box 260 to the first power distribution unit 600.

The first power distribution unit 600 may be configured to output the HV power to other components, including routing the HV power to the second power distribution unit 610 via a dedicated electrical coupling 945. The power distribution units 600 and 610 may be deployed as part of the electrical control system 155 to provide power output ports to supply HV power to electrification components within the electric vehicle. For lower level power, such as 24 V or 12 V power signals, each of the power distribution units 600 and 610 is electrically coupled to the DC-DC power converter 270. The power converter 270 features logic to convert HV power into power at lower voltages. For example, the power converter 270 may convert 400 V power signaling into power signals of lesser voltages such as 24 V power signals or 12 V power signals for dissemination to electrification components that rely on low-level voltages.

Herein, the flow of power during a charging state of the electric vehicle, a charger 250 is configured to manage the charging of the battery packs 165, 170, 175 and/ 180 of the battery system 160 that are installed within the electric vehicle. More specifically, the charger 250 includes a charging interface (not shown) that is located facing the front end 204 of the protective housing (not shown) to receive a supply voltage from a voltage source. The voltage source may correspond to a HV charging station for example. During charging, the charger 250 is configured to convert the supply HV power from the charging station into a power level that is safe for use by the electrical control system 155. The converted supply HV power is provided to the HV junction box 260 and re-routed to the battery system 160 via the HV power cables 905-908 for re-charging the battery packs 165, 170, 175 and/or 180.

In the foregoing description, the invention is described with reference to specific exemplary embodiments thereof. However, it will be evident that various modifications and changes may be made thereto without departing from the broader spirit and scope of the invention.

What is claimed is:

1. A protective housing for a central electrical system deployed within an electric vehicle, the protective housing comprising:
a first housing layer to support and protect one or more power distribution units;
a second housing layer positioned above the first housing layer, the second housing layer to support and protect a power charger; and
a third housing layer positioned above the second housing layer, the third housing layer to support a high-voltage junction box.

2. The protective housing of claim 1, wherein the high-voltage junction box comprises a first interface including a first plurality of power ports adapted for coupling to a first plurality of power cables connected with battery packs installed within the electric vehicle.

3. The protective housing of claim 2, wherein the high-voltage junction box comprises a second interface including a second plurality of power ports for coupling to a plurality of power ports associated with a power input/output (I/O) interface of a first power distribution unit of the one or more power distribution units.

4. The protective housing of claim 3, wherein the second plurality of power ports is exposed and accessible from a first end of the protective housing while the plurality of power ports associated with the power I/O interface of the first power distribution unit is also exposed and accessible from the first end of the protective housing.

5. The protective housing of claim 1, wherein the power charger is configured to receive high-voltage input power from a charging source and route the high-voltage input power to the high-voltage junction box for routing the high-voltage input power to the battery packs over the first plurality of power cables.

6. The protective housing of claim 1 further comprising:
a power converter coupled to members forming the protective housing that are located on a back end of the protective housing.

7. The protective housing of claim 6, wherein the one or more power distribution units are configured to disseminate high-voltage power exceeding 200 volts to electrification components of the electric vehicle and the power converter is configured to disseminate low-voltage power less than 24 volts to electrification components of the electric vehicle.

8. A protective housing for a central electrical system deployed within an electric vehicle, the protective housing comprising:
a first housing layer to support and protect one or more power distribution units;
a second housing layer positioned above the first housing layer, the second housing layer to support and protect a power charger; and
a third housing layer positioned above the second housing layer, the third housing layer to support a high-voltage junction box.

9. The protective housing of claim 8, wherein the high-voltage junction box comprises a first interface including a first plurality of power ports adapted for coupling to a first plurality of power cables connected with battery packs installed within the electric vehicle.

10. The protective housing of claim 9, wherein the high-voltage junction box comprises a second interface including a second plurality of power ports for coupling to a plurality of power ports associated with a power input/output (I/O) interface of a first power distribution unit of the one or more power distribution units.

11. The protective housing of claim 10, wherein the second plurality of power ports is exposed and accessible from a first end of the protective housing while the plurality of power ports associated with the power I/O interface of the first power distribution unit is also exposed and accessible from the first end of the protective housing.

12. The protective housing of claim 8, wherein the power charger is configured to receive high-voltage input power from a charging source and route the high-voltage input power to the high-voltage junction box for routing the high-voltage input power to the battery packs over the first plurality of power cables.

13. The protective housing of claim 8 further comprising:
a power converter coupled to members forming the protective housing that are located on a back end of the protective housing.

14. The protective housing of claim 13, wherein the one or more power distribution units are configured to disseminate high-voltage power exceeding 200 volts to electrification components of the electric vehicle and the power converter is configured to disseminate low-voltage power less than 24 volts to electrification components of the electric vehicle.
